(19) United States
(12) Patent Application Publication
(10) Pub. No.: US 2025/0343032 A1
(43) Pub. Date: Nov. 6, 2025

(54) SUBSTRATE PROCESSING APPARATUS WITH TEMPERATURE CONTROLLER

(71) Applicant: ASM IP Holding B.V., Almere (NL)

(72) Inventor: Hirotsugu Sugiura, Tokyo (JP)

(21) Appl. No.: 19/194,543

(22) Filed: Apr. 30, 2025

Related U.S. Application Data
(60) Provisional application No. 63/641,501, filed on May 2, 2024.

(51) Int. Cl. H01J 37/32; C23C 16/455; C23C 16/52

(52) U.S. Cl. CPC H01J 37/32522; C23C 16/45565; C23C 16/4557; C23C 16/52; H01J 37/32449; H01J 37/32862; H01J 2237/3321

(57) ABSTRACT

An apparatus for processing a substrate may comprise a reaction chamber defined in part by a chamber wall; a wall heating unit disposed in the chamber wall; a substrate support disposed within the reaction chamber to support a substrate; a showerhead constructed and arranged to face the substrate support; a showerhead heating unit disposed in the showerhead; and a controller configured to control temperatures of the wall heating unit and the showerhead heater unit; wherein a temperature of the wall heating unit is configured to be controlled between 50° C. and about 150° C.; wherein a temperature of the showerhead heating unit (20) is configured to be controlled between 150° C. and about 300° C.

### CROSS-REFERENCE TO RELATED APPLICATIONS

This application claims priority to U.S. Provisional Patent Application Ser. No. 63/641,501 filed May 2, 2024 SUBSTRATE PROCESSING APPARATUS WITH TEMPERATURE CONTROLLER, the disclosure of which is hereby incorporated by reference in its entirety.

### FIELD OF INVENTION

The present disclosure relates generally to a substrate processing apparatus and particularly a substrate processing apparatus with a temperature controller.

### BACKGROUND OF THE DISCLOSURE

Integrated circuits comprise multiple layers of materials deposited by various techniques, including Chemical Vapor Deposition (CVD), Atomic Layer Deposition (ALD), Plasma Enhanced CVD (PECVD), and Plasma Enhanced ALD (PEALD). As such, the deposition of materials on a semiconductor substrate is a critical step in the process of producing integrated circuits.

PECVD has a high deposition rate compared with that of PEALD; however, further improvement of process throughput is needed. One of methods to improve the throughput is to use multiple depositions without a cleaning step.

Reactor chamber environment using multiple depositions may not be uniform for each deposition substrate because cleaning and pre-coating are not carried out for every wafer. For example, when a cleaning step is conducted after 3 depositions, the 2^{nd} and 3^{rd} substrate have a different chamber condition compared with 1st substrate.

This difference may cause instabilities of particles and thickness non-uniformities. The reason why the instabilities happen may be due to low-k material nature. Low-k material usually includes Si, O, C, H of organic structure. To keep a low dielectric constant, an organic structure may act an important role to form porosity. However, the organic structure may cause degassing or condensation in a reaction chamber, resulting in particles and thickness instability.

Any discussion, including discussion of problems and solutions, set forth in this section, has been included in this disclosure solely for the purpose of providing a context for the present disclosure, and should not be taken as an admission that any or all of the discussion was known at the time the invention was made or otherwise constitutes prior art.

### SUMMARY OF THE DISCLOSURE

This summary is provided to introduce a selection of concepts in a simplified form. These concepts are described in further detail in the detailed description of example embodiments of the disclosure below. This summary is not intended to identify key features or essential features of the claimed subject matter, nor is it intended to be used to limit the scope of the claimed subject matter.

In some embodiments, an apparatus for processing a substrate is provided. The apparatus may comprise a reaction chamber defined in part by a chamber wall; a wall heating unit disposed in the chamber wall; a substrate support disposed within the reaction chamber to support a substrate; a showerhead constructed and arranged to face the substrate support; a showerhead heating unit disposed in the showerhead; and a controller configured to control temperatures of the wall heating unit and the showerhead heater unit; wherein a temperature of the wall heating unit is configured to be controlled between 50° C. and about 150° C.; wherein a temperature of the showerhead heating unit (20) is configured to be controlled between 150° C. and about 300° C.

In accordance with further exemplary embodiments of the disclosure, the difference between the temperature of the wall heating unit and the temperature of the showerhead heating unit may be at least 60° C.

In accordance with further exemplary embodiments of the disclosure, the temperature of the wall heating unit may be configured to be controlled between 100° C. and about 135° C.

In accordance with further exemplary embodiments of the disclosure, the temperature of the showerhead heating unit may be configured to be controlled between 210° C. and about 230° C.

In accordance with further exemplary embodiments of the disclosure, the wall heating unit may comprise a cartridge heater.

In accordance with further exemplary embodiments of the disclosure, the showerhead heating unit may comprise a cartridge heater.

In accordance with further exemplary embodiments of the disclosure, a temperature of the substrate support may range between 200° C. and about 400° C.

In accordance with further exemplary embodiments of the disclosure, a pressure in the reaction chamber may range between about 100 Pa and about 1,100 Pa.

In accordance with further exemplary embodiments of the disclosure, the substrate processing apparatus may comprise a plasma enhanced chemical vapor deposition apparatus.

In accordance with further exemplary embodiments of the disclosure, a RF power to produce a plasma may range between 100 W and 4,500 W.

In accordance with further exemplary embodiments of the disclosure, a RF frequency of the plasma may range between 1 MHz and 100 MHz.

In accordance with further exemplary embodiments of the disclosure, a method of depositing a thin film is provided. The method may comprise steps of: a) placing a substrate on a substrate support in a reaction chamber, wherein the reaction chamber is defined in part by a chamber wall; b) introducing gases to the reaction chamber through a showerhead; and c) providing a plasma to the reaction chamber to form a thin film; wherein a temperature of the chamber wall is configured to be controlled between 50° C. and about 150° C.; and wherein a temperature of the showerhead is configured to be controlled between 150° C. and about 300° C.

In accordance with further exemplary embodiments of the disclosure, the gases may comprise a precursor, an oxygen-containing gas, and an inert gas.

In accordance with further exemplary embodiments of the disclosure, the precursor may comprise at least one of: octamethylcyclotetrasiloxane (OMCTS), tetramethylcyclotetrasiloxane (TMCTS), octamethoxydodecasiloxane (OMODDS), octamethoxycyclioiloxane, dimethyldimethoxysilane (DM-DMOS), diethoxymethlsilane (DEMS), dimethoxymethylsilane (DMOMS), phenoxydimethylsilane (PODMS), dimethyldioxosilylcyclohexane (DMDOSH), 1,3-dimethoxytetramethyldisiloxane (DMOTMDS), dimethoxydiphenylsilane (DMDPS), Vinylmethyldimethoxysilane (VMDMOS), or dicyclopentyldimethoxysilane (DcPDMS).

In accordance with further exemplary embodiments of the disclosure, the oxygen-containing gas may comprise at least one of: O2, O3, N2O, N2O4, NxOy, CO, CO2, H2O, or H2O2.

In accordance with further exemplary embodiments of the disclosure, the method may further comprise step (d) removing the substrate from the reaction chamber.

In accordance with further exemplary embodiments of the disclosure, the method may further comprise step (f) introducing a cleaning gas to the reaction chamber.

In accordance with further exemplary embodiments of the disclosure, the steps (a) to (d) may be repeated N times before the step (f).

In accordance with further exemplary embodiments of the disclosure, a thickness of the thin film is at least 500 nm.

These and other embodiments will become readily apparent to those skilled in the art from the following detailed description of certain embodiments having reference to the attached figures; the invention not being limited to any particular embodiment(s) disclosed.

### BRIEF DESCRIPTION OF THE DRAWING FIGURES

A more complete understanding of exemplary embodiments of the present disclosure can be derived by referring to the detailed description and claims when considered in connection with the following illustrative figures.

FIG. 1 illustrates a plasma apparatus in accordance with exemplary embodiments of the disclosure.

FIG. 2 illustrates a schematic image of 10 wafers continuous run test without cleaning step in accordance with exemplary embodiments of the disclosure.

FIG. 3 illustrates a schematic image of 10 wafers continuous run test without cleaning step in accordance with exemplary embodiments of the disclosure.

It will be appreciated that elements in the figures are illustrated for simplicity and clarity and have not necessarily been drawn to scale. For example, the dimensions of some of the elements in the figures may be exaggerated relative to other elements to help improve understanding of illustrated embodiments of the present disclosure.

### DETAILED DESCRIPTION OF EXEMPLARY EMBODIMENTS

Although certain embodiments and examples are disclosed below, it will be understood by those in the art that the invention extends beyond the specifically disclosed embodiments and/or uses of the invention and obvious modifications and equivalents thereof. Thus, it is intended that the scope of the invention disclosed should not be limited by the particular disclosed embodiments described below.

As used herein, the term “substrate” may refer to any underlying material or materials, including any underlying material or materials that may be modified, or upon which, a device, a circuit, or a film may be formed. The “substrate” may be continuous or non-continuous; rigid or flexible; solid or porous; and combinations thereof. The substrate may be in any form, such as a powder, a plate, or a workpiece. Substrates in the form of a plate may include wafers in various shapes and sizes. Substrates may be made from semiconductor materials, including, for example, silicon, silicon germanium, silicon oxide, gallium arsenide, gallium nitride and silicon carbide.

As examples, a substrate in the form of a powder may have applications for pharmaceutical manufacturing. A porous substrate may comprise polymers. Examples of workpieces may include medical devices (for example, stents and syringes), jewelry, tooling devices, components for battery manufacturing (for example, anodes, cathodes, or separators) or components of photovoltaic cells, etc.

A continuous substrate may extend beyond the bounds of a process chamber where a deposition process occurs. In some processes, the continuous substrate may move through the process chamber such that the process continues until the end of the substrate is reached. A continuous substrate may be supplied from a continuous substrate feeding system to allow for manufacture and output of the continuous substrate in any appropriate form.

Non-limiting examples of a continuous substrate may include a sheet, a non-woven film, a roll, a foil, a web, a flexible material, a bundle of continuous filaments or fibers (for example, ceramic fibers or polymer fibers). Continuous substrates may also comprise carriers or sheets upon which non-continuous substrates are mounted.

The illustrations presented herein are not meant to be actual views of any particular material, structure, or device, but are merely idealized representations that are used to describe embodiments of the disclosure.

The particular implementations shown and described are illustrative of the invention and its best mode and are not intended to otherwise limit the scope of the aspects and implementations in any way. Indeed, for the sake of brevity, conventional manufacturing, connection, preparation, and other functional aspects of the system may not be described in detail. Furthermore, the connecting lines shown in the various figures are intended to represent exemplary functional relationships and/or physical couplings between the various elements. Many alternative or additional functional relationship or physical connections may be present in the practical system, and/or may be absent in some embodiments.

It is to be understood that the configurations and/or approaches described herein are exemplary in nature, and that these specific embodiments or examples are not to be considered in a limiting sense, because numerous variations are possible. The specific routines or methods described herein may represent one or more of any number of processing strategies. Thus, the various acts illustrated may be performed in the sequence illustrated, in other sequences, or omitted in some cases.

The subject matter of the present disclosure includes all novel and nonobvious combinations and subcombinations of the various processes, systems, and configurations, and other features, functions, acts, and/or properties disclosed herein, as well as any and all equivalents thereof.

In this disclosure, “gas” may include material that is a gas at normal temperature and pressure, a vaporized solid and/or a vaporized liquid, and may be constituted by a single gas or a mixture of gases, depending on the context. A gas introduced without passing through a gas supply unit, such as a shower plate, or the like, may be used for, e.g., sealing the reaction space, and may include a seal gas, such as a rare or other inert gas. The term inert gas, carrier gas, and dilution gas refer to a gas that does not take part in a chemical reaction to an appreciable extent and/or a gas that may excite a precursor when plasma power is applied.

As used herein, the term “film” and “thin film” may refer to any continuous or non-continuous structures and material deposited by the methods disclosed herein. For example, “film” and “thin film” could include 2D materials, nanorods, nanotubes, or nanoparticles or even partial or full molecular layers or partial or full atomic layers or clusters of atoms and/or molecules. “Film” and “thin film” may comprise material or a layer with pinholes, but still be at least partially continuous.

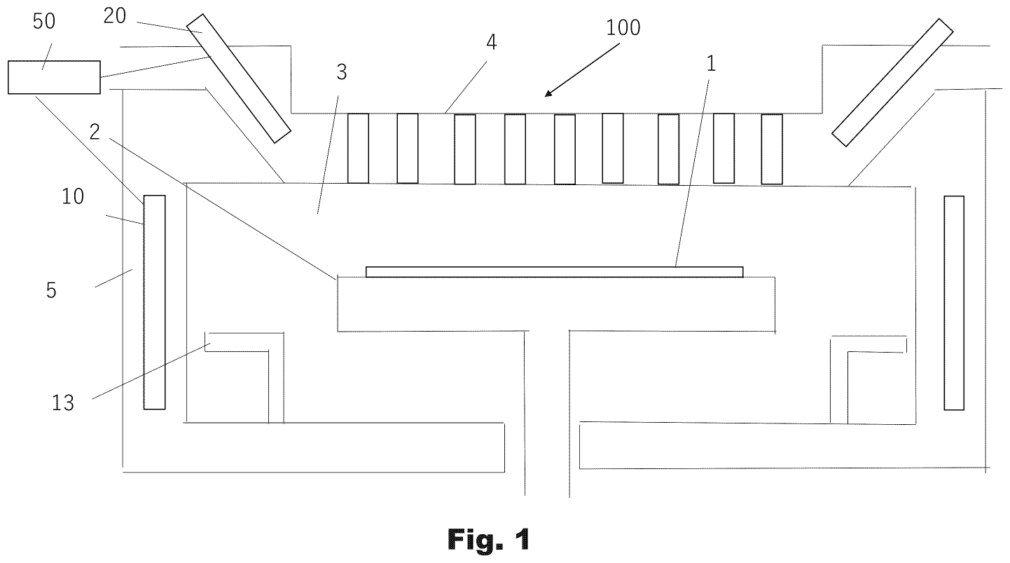

FIG. 1 illustrates a plasma apparatus 100 in accordance with exemplary embodiments of the disclosure is illustrated. The plasma apparatus 100 may be used to perform one or more steps or sub steps as described herein and/or to form one or more structures or portions thereof as described herein.

The apparatus 100 may comprise: a reaction chamber 3 defined in part by a chamber wall 5; a substrate support 2 disposed within the reaction chamber 3 to support a substrate 1; and a showerhead 4 constructed and arranged to face the substrate support 2. A temperature of the substrate support 2 may range between 200° C. and about 400° C. A pressure in the reaction chamber 3 may range between about 100 Pa and about 1,100 Pa.

The substrate support 2 and the showerhead 4 may serve as electrically conductive flat-plate electrodes. A plasma may be excited within the reaction chamber 3 by applying, for example, an RF power from a RF generator to one electrode (e.g., showerhead 4) via RF matcher and electrically grounding the other electrode (e.g., substrate support 2). The RF power may range between 100 W and 4,500 W. A RF frequency of the plasma may range between 1 MHz and 100 MHz (e.g., 13.56 MHz, 27 MHz, or 60 MHz).

Gases may be introduced into the reaction chamber 3 through the showerhead 4. In the reaction chamber 3, a circular duct 13 with an exhaust line may be provided, through which gas in the reaction chamber 3 may be exhausted.

The gases may comprise a precursor, an oxygen-containing gas, and an inert gas.

The precursor may comprise at least one of: octamethylcyclotetrasiloxane (OMCTS), tetramethylcyclotetrasiloxane (TMCTS), octamethoxydodecasiloxane (OMODDS), octamethoxycyclioiloxane, dimethyldimethoxysilane (DM-DMOS), diethoxymethlsilane (DEMS), dimethoxymethylsilane (DMOMS), phenoxydimethylsilane (PODMS), dimethyldioxosilylcyclohexane (DMDOSH), 1,3-dimethoxytetramethyldisiloxane (DMOTMDS), dimethoxydiphenylsilane (DMDPS), Vinylmethyldimethoxysilane (VMDMOS), or dicyclopentyldimethoxysilane (DcPDMS).

The oxygen-containing gas may comprise at least one of: O2, O3, N2O, N2O4, NxOy, CO, CO2, H2O, or H2O2.

The apparatus 100 may further comprise: a wall heating unit 10 disposed in the chamber wall 5; a showerhead heating unit 20 disposed in the showerhead 4; and a controller 50 configured to control temperatures of the wall heating unit 10 and the showerhead heater unit 20. The wall heating unit 10 may comprise a cartridge heater. The showerhead heating unit 20 may comprise a cartridge heater also.

A temperature of the wall heating unit 10 may be configured to be controlled between 50° C. and 150° C., preferably between 100° C. and 135° C. A temperature of the showerhead heating unit 20 may be configured to be controlled between 150° C. and about 300° C., preferably between 210° C. and 230° C. The difference between the temperature of the wall heating unit 10 and the temperature of the showerhead heating unit 20 may be at least 60° C.

The apparatus 500 may perform steps to form a thin film. The steps may comprise: a) placing a substrate 1 on the substrate support 2 in the reaction chamber 3; b) introducing gases to the reaction chamber 3 through the showerhead 4; and c) providing a plasma to the reaction chamber 3 to form a thin film. A temperature of the chamber wall may be configured to be controlled between 50° C. and about 150° C. and a temperature of the showerhead may be configured to be controlled between 150° C. and about 300° C.

The method may further comprise step (d) removing the substrate 1 from the reaction chamber 3. The method may further comprise step (f) introducing a cleaning gas to the reaction chamber 3. The steps (a) to (d) may be repeated N times before the step (f). A thickness of the thin film may be at least 500 nm.

To prevent particles, relatively low temperature of the chamber wall 5 may be effective. When the temperature of the wall hearing unit 10 is 130° C., unreacted precursors may be kept on the chamber wall 5 than that of 150° C. because of vapor pressure. Therefore, the particles in the reaction chamber 3 may be reduced.

Further, to prevent particles, relatively higher temperature of the showerhead 4 may be effective. When the temperature of the showerhead 4 is low, the showerhead 4 may have a thick film on it, causing more chances to generate particles because degassing amount may increase from the showerhead 4.

Our test result indicates that the combination of the showerhead heating unit at about 220° C. and the wall heating unit at about 130° C. shows a good performance. A result of multiple depositions without cleaning may cause higher counts of particles.

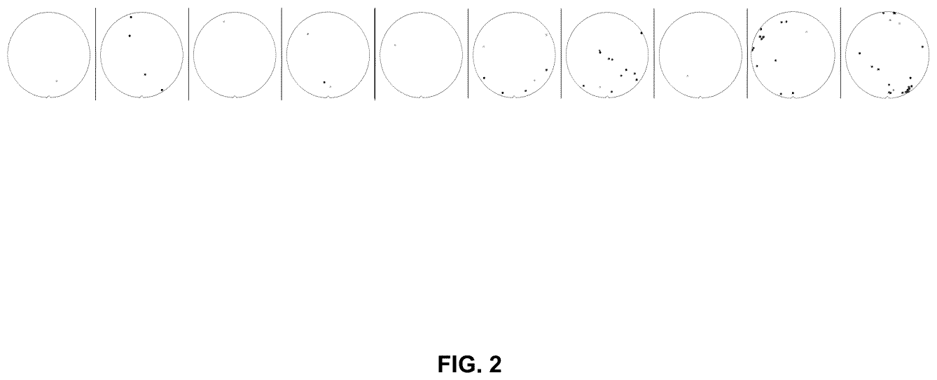

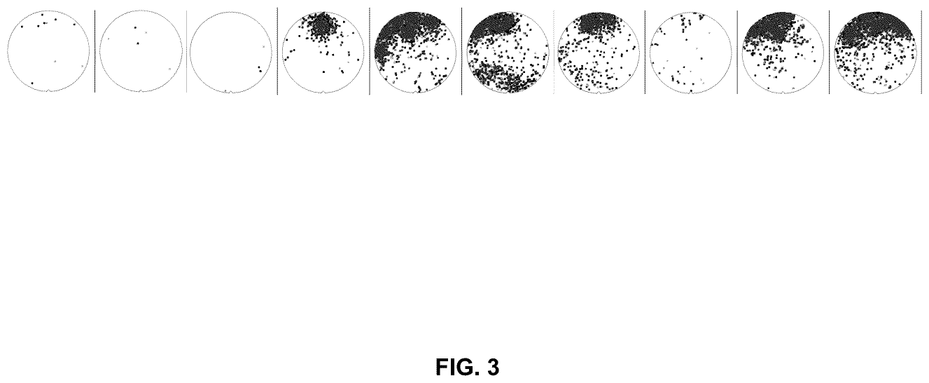

FIG. 2 and FIG. 3 illustrate schematic images of 10 wafers continuous run results without cleaning steps in accordance with exemplary embodiments of the disclosure. The result in FIG. 2 shows when the temperature of the showerhead heating unit is about 220° C. while the result in FIG. 3 shows when the temperature of the showerhead heating unit is about 230° C.

Even after 8 wafers are proceeded, the number of particles is limited when the temperature of the showerhead heating unit is 220° C. On the other hand, as shown in FIG. 3, large particles are generated after 3 wafers when the temperature of the showerhead heating unit is 230° C. The absorption and desorption rate of the deposition species on the showerhead depend on the showerhead temperature. More desorption occurs at 230° C. than at 220° C. The desorbed deposition species from the showerhead may increase the particle generation in the plasma. The result may indicate that the balance between desorption rate on the showerhead and the absorption rate of on the chamber wall is the key to control generation of particles in the plasma.

The example embodiments of the disclosure described above do not limit the scope of the invention, since these embodiments are merely examples of the embodiments of the invention. Any equivalent embodiments are intended to be within the scope of this invention. Indeed, various modifications of the disclosure, in addition to those shown and described herein, such as alternative useful combinations of the elements described, may become apparent to those skilled in the art from the description. Such modifications and embodiments are also intended to fall within the scope of the appended claims.

What is claimed is:

1. An apparatus for processing a substrate, comprising:
a reaction chamber defined in part by a chamber wall;
a wall heating unit disposed in the chamber wall;
a substrate support disposed within the reaction chamber to support a substrate;
a showerhead constructed and arranged to face the substrate support;
a showerhead heating unit disposed in the showerhead; and
a controller configured to control temperatures of the wall heating unit and the showerhead heater unit;
wherein a temperature of the wall heating unit is configured to be controlled between 50° C. and about 150° C.;
wherein a temperature of the showerhead heating unit is configured to be controlled between 150° C. and about 300° C.

2. The apparatus of claim 1, wherein the difference between the temperature of the wall heating unit and the temperature of the showerhead heating unit is at least 60° C.

3. The apparatus of claim 1, wherein the temperature of the wall heating unit is configured to be controlled between 100° C. and about 135° C.

4. The apparatus of claim 1, wherein the temperature of the showerhead heating unit is configured to be controlled between 210° C. and about 230° C.

5. The apparatus of claim 1, wherein the wall heating unit comprises a cartridge heater.

6. The apparatus of claim 1, wherein the showerhead heating unit comprises a cartridge heater.

7. The apparatus of claim 1, wherein a temperature of the substrate support ranges between 200° C. and about 400° C.

8. The apparatus of claim 1, wherein a pressure in the reaction chamber ranges between about 100 Pa and about 1,100 Pa.

9. The apparatus of claim 1, wherein the substrate processing apparatus comprise a plasma enhanced chemical vapor deposition apparatus.

10. The apparatus of claim 9, wherein a RF power to produce a plasma ranges between 100 W and 4,500 W.

11. The apparatus of claim 10, wherein a RF frequency of the plasma ranges between 1 MHZ and 100 MHz.

12. A method of depositing a thin film,
the method comprising steps of:
a) placing a substrate on a substrate support in a reaction chamber, wherein the reaction chamber is defined in part by a chamber wall;
b) introducing gases to the reaction chamber through a showerhead; and
c) providing a plasma to the reaction chamber to form a thin film;
wherein a temperature of the chamber wall is configured to be controlled between 50° C. and about 150° C.; and
wherein a temperature of the showerhead is configured to be controlled between 150° C. and about 300° C.

13. The method of claim 12, wherein the gases comprise a precursor, an oxygen-containing gas, and an inert gas.

14. The method of claim 13, wherein the precursor comprises at least one of: octamethylcyclotetrasiloxane (OMCTS), tetramethylcyclotetrasiloxane (TMCTS), octamethoxydodecasiloxane (OMODDS), octamethoxycyclioiloxane, dimethyldimethoxysilane (DM-DMOS), diethoxymethlsilane (DEMS), dimethoxymethylsilane (DMOMS), phenoxydimethylsilane (PODMS), dimethyldioxosilylcyclohexane (DMDOSH), 1,3-dimethoxytetramethyldisiloxane (DMOTMDS), dimethoxydiphenylsilane (DMDPS), Vinylmethyldimethoxysilane (VMDMOS), or dicyclopentyldimethoxysilane (DcPDMS).

15. The method of claim 13, wherein the oxygen-containing gas comprises at least one of: O2, O3, N2O, N2O4, NxOy, CO, CO2, H2O, or H2O2.

16. The method of claim 12, further comprising step (d) removing the substrate from the reaction chamber.

17. The method of claim 16, further comprising step (f) introducing a cleaning gas to the reaction chamber.

18. The method of claim 17, wherein the steps (a) to (d) are repeated N times before the step (f).

19. The method of claim 12, wherein a thickness of the thin film is at least 500 nm.
